(19) United States
(12) Patent Application Publication
(10) Pub. No.: US 2025/0355030 A1
(43) Pub. Date: Nov. 20, 2025

(54) ANTENNA MEASUREMENT METHOD AND SYSTEM

(71) Applicant: TRON FUTURE TECH INC., HSINCHU CITY (TW)

(72) Inventors: SHIH-KAI LIN, HSINCHU CITY (TW); HONG-YU JIANG, HSINCHU CITY (TW)

(21) Appl. No.: 19/185,297

(22) Filed: Apr. 22, 2025

Related U.S. Application Data
(60) Provisional application No. 63/647,620, filed on May 15, 2024.

(51) Int. Cl. G01R 29/08; G01R 29/10

(52) U.S. Cl. CPC G01R 29/0892; G01R 29/0878; G01R 29/105

(57) ABSTRACT

An antenna measurement method includes: generating a first electrical signal and a second electrical signal by processing an input signal sent from an analyzer according to control information; driving a dual-polarized antenna to emit an electromagnetic signal toward an antenna under test (AUT) by feeding the first electrical signal and the second electrical signal to the dual-polarized antenna, an output signal being outputted from the AUT in response to the electromagnetic signal; utilizing the analyzer to generate analysis data according to the input signal and the output signal; and obtaining a polarization characteristic of the AUT by applying a predetermined data processing operation corresponding to the control information to the analysis data.

### PRIORITY CLAIM AND CROSS-REFERENCE

The present application claims priority to U.S. Provisional Patent Applications including Ser. No. 63/647,620, filed on May 15, 2024, which is incorporated by reference herein in its entirety.

### BACKGROUND

The present disclosure relates to antenna measurement, more particularly, to an antenna measurement method for determining polarization characteristics, and an antenna measurement system.

Beyond 5G (B5G) represents the next leap in wireless communication, offering ultra-high data rates, low latency, and massive connectivity to support advanced applications such as autonomous vehicles, smart cities, and high-resolution radar systems. A cornerstone of B5G is phased array antennas, which play a pivotal role in both communication and radar technologies by providing beamforming, adaptive beam steering, and improved spatial resolution. Accurate antenna measurement is critical for optimizing performance and ensuring compliance with B5G standards. Measurement techniques may include far-field measurements, near-field measurements, and over-the-air (OTA) testing. These methods provide essential insights into antenna behavior, ensuring the successful implementation of B5G technologies across diverse applications.

### SUMMARY

The described embodiments provide an antenna measurement method for determining polarization characteristics, and an antenna measurement system.

Some embodiments described herein may include an antenna measurement method. The antenna measurement method includes: generating a first electrical signal and a second electrical signal by processing an input signal sent from an analyzer according to control information; driving a dual-polarized antenna to emit an electromagnetic signal toward an antenna under test (AUT) by feeding the first electrical signal and the second electrical signal to the dual-polarized antenna, an output signal being outputted from the AUT in response to the electromagnetic signal; utilizing the analyzer to generate analysis data according to the input signal and the output signal; and obtaining a polarization characteristic of the AUT by applying a predetermined data processing operation corresponding to the control information to the analysis data.

Some embodiments described herein may include an antenna measurement system. The antenna measurement system includes a dual-polarized antenna, an analyzer, a processing circuit and a signal generator. The dual-polarized antenna is configured to receive a first electrical signal and a second electrical signal to emit an electromagnetic signal toward an antenna under test (AUT). An output signal is generated from the AUT in response to the electromagnetic signal. The analyzer is configured to generate an input signal, receive the output signal from the AUT, and generate analysis data according to the input signal and the output signal. The processing circuit, coupled to the analyzer, is configured to obtain a polarization characteristic of the AUT by applying a predetermined data processing operation to the analysis data. The signal generator, coupled to the dual-polarized antenna and the analyzer, is configured to generate the first electrical signal and the second electrical signal by processing the input signal according to control information corresponding to the predetermined data processing operation.

Some embodiments described herein may include an antenna measurement system. The antenna measurement system includes a dual-polarized antenna, an electronic device and a network analyzer. The dual-polarized antenna is configured to receive a first electrical signal and a second electrical signal to emit an electromagnetic signal toward an antenna under test (AUT). An output signal is generated from the AUT in response to the electromagnetic signal. The electronic device, coupled to the dual-polarized antenna, is configured to generate the first electrical signal and the second electrical signal by performing amplitude scaling and phase shifting on an input signal. The network analyzer, coupled to the dual-polarized antenna and the electronic device, is configured to generate the input signal, receive the output signal from the AUT, and generate analysis data according to the input signal and the output signal.

By adjusting the signal characteristics (e.g., amplitude and/or phase) of the excitation signals for the reference antenna, the proposed antenna measurement scheme can realize rapid synthesis or modification of the polarization characteristics of the electromagnetic signal directed toward the AUT, thereby significantly enhancing the measurement efficiency and accuracy for antenna array systems with a large number of antenna elements. Even if an output signal of the AUT is produced by combining response signals corresponding to horizontal and vertical polarization components of the electromagnetic signal, the proposed antenna measurement scheme can effectively identify the polarization characteristics of the AUT.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an implementation of an array unit in accordance with some embodiments of the present disclosure.

FIG. 2 is a diagram illustrating an exemplary antenna measurement system in accordance with some embodiments of the present disclosure.

FIG. 3 illustrates an implementation of the antenna measurement system shown in FIG. 2 in accordance with some embodiments of the present disclosure.

FIG. 4A illustrates an implementation of the electronic device shown in FIG. 3 in accordance with some embodiments of the present disclosure.

FIG. 4B illustrates another implementation of the electronic device shown in FIG. 3 in accordance with some embodiments of the present disclosure.

FIG. 4C illustrates another implementation of the electronic device shown in FIG. 3 in accordance with some embodiments of the present disclosure.

FIG. 5 is a flow chart of the measurement process in the antenna measurement system shown in FIG. 3 in accordance with some embodiments of the present disclosure.

FIG. 6 is a diagram illustrating the locus of the tip of the electric field vector associated with the electromagnetic signal, emitted when the antenna measurement system shown in FIG. 3 operates in a dual-linear polarization measurement configuration, in accordance with some embodiments of the present disclosure.

FIG. 7 is a diagram illustrating the locus of the tip of the electric field vector associated with the electromagnetic signal, emitted when the antenna measurement system shown in FIG. 3 operates in a circular polarization measurement configuration, in accordance with some embodiments of the present disclosure.

FIG. 8 is a diagram illustrating the locus of the tip of the electric field vector associated with the electromagnetic signal, emitted when the antenna measurement system shown in FIG. 3 operates in a dual-orthogonal polarization measurement, in accordance with some embodiments of the present disclosure.

FIG. 9 is a diagram illustrating the locus of the tip of the electric field vector associated with the electromagnetic signal, emitted when the antenna measurement system shown in FIG. 3 operates in a rotating linear polarization measurement, in accordance with some embodiments of the present disclosure.

FIG. 10 is a flow chart of an exemplary antenna measurement method in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Communication architectures for Beyond 5G (B5G) applications may include a transmitter (TX) antenna array system and a receiver (RX) antenna array system. When the TX antenna array system is measured, a circularly polarized radiation pattern may be obtained using a measurement method similar to dual polarization. However, the dual-polarization measurement method may not be suitable for measuring the RX antenna array system. For example, when there is no mechanism available to measure phases, even though the magnitudes of two polarizations can be measured, the dual polarization measurement method may not be able to measure the RX antenna array system.

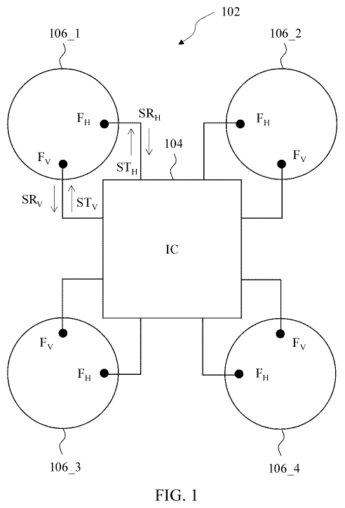

Referring to FIG. 1, an implementation of an array unit is illustrated in accordance with some embodiments of the present disclosure. The array unit 102 may serve as at least a portion of an antenna array system. The array unit 102 includes, but is not limited to, an integrated circuit (or chip) 104 and antenna elements 1061 to 106_4.

In a case where the array unit 102 operates as a transmission end for antenna measurement, the integrated circuit (IC) 104 is configured to transmit electrical signals to each antenna element, thereby exciting each antenna element to generate a circularly polarized wave. For example, the electrical signal ST_{H} inputted to the feed point F_{H} of the antenna element 106_1 may be expressed as +b·cos(ω₀t)−a·sin(ω₀t), while the electrical signal ST_{V} inputted to the feed point F_{V} of the antenna element 106_1 may be expressed as +a·cos(ω₀t)+b·sin(ω₀t), where t denotes time. The IC 104 may configure the coefficient a, the coefficient b, and the angular frequency co according to design requirements, thereby determining the respective amplitudes and phases of the electrical signals ST_{H} and ST_{V}. The antenna element 106_1 may generate a left-hand circularly polarized wave according to the electrical signals ST_{H} and ST_{V} that have equal amplitudes but differ in phase by 90 degrees. As another example, the electrical signal ST_{H} inputted to the feed point F_{H} may be expressed as −b·cos(ω₀t)+a·sin(ω₀t), while the electrical signal ST_{V} inputted to the feed point F_{V} may be expressed as +a·cos(ω₀t)+b·sin(ω₀t). The antenna element 106_1 may generate a right-hand circularly polarized wave according to the electrical signals ST_{H} and ST_{V} that have equal amplitudes but differ in phase by 90 degrees. In other words, the array unit 102 can produce a predetermined circularly polarized radiation pattern by controlling electrical signals inputted to the antenna elements 1061 to 106_4.

In a case where the array unit 102 operates as a reception end for antenna measurement, the IC 104 receives electrical signals outputted from the feed points F_{H} and F_{V} of each antenna element. However, these signals are combined within the IC 104, making it difficult to determine the phase difference between these signals. For example, when the antenna element 106_1 is configured to receive a left-hand circularly polarized wave to generate electrical signals SR_{H} and SR_{V} that have equal amplitudes but differ in phase by 90 degrees, the electrical signals SR_{H} and SR_{V} may be expressed as α·sin(ω₀t) and α·cos(ω₀t) respectively; when the antenna element 106_1 is configured to receive a right-hand circularly polarized wave to generate the electrical signals SR_{H} and SR_{V} that have equal amplitudes but differ in phase by 90 degrees, the electrical signals SR_{H} and SR_{V} may be expressed as α·cos(ω₀t) and α·sin(ω₀t) respectively. As the electrical signals SR_{H} and SR_{V} are combined within the IC 104, the phase difference between them cannot be determined, thereby preventing the IC 104 from distinguishing whether the electrical signals SR_{H} and SR_{V} correspond to a right-hand or left-hand circularly polarized wave.

The present disclosure describes exemplary antenna measurement systems, each of which can drive a reference antenna at a transmission end to emit electromagnetic signals toward an antenna under test (AUT) at a reception end in response to control information determined based on a predetermined data processing operation. For example, the exemplary antenna measurement system may include an electronic device, which is configured to control excitation signals inputted to the reference antenna according to the control information. When or after receiving response signals that are generated by the AUT in response to the electromagnetic signals, the exemplary antenna measurement system can process the response signals according to the predetermined data processing operation to thereby measure polarization characteristics of the AUT, such as an axial ratio. The present disclosure further describes exemplary antenna measurement methods. By leveraging the correspondence between the predetermined data processing operation and the control information, the proposed antenna measurement scheme can effectively identify the polarization characteristics of the AUT even if the response signals outputted by the AUT are formed by combining electrical signals corresponding to horizontal and vertical polarizations. Further description is provided below.

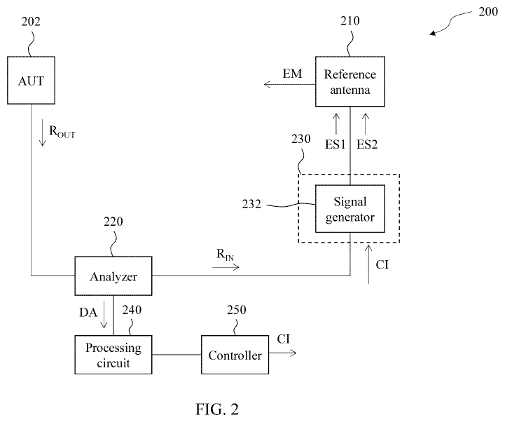

FIG. 2 is a diagram illustrating an exemplary antenna measurement system in accordance with some embodiments of the present disclosure. The antenna measurement system 200 can be configured to measure the polarization characteristics of an AUT 202 in a reception mode and/or a transmission mode. The AUT 202 may include one or more antenna elements. By way of example but not limitation, the AUT 202 may be an antenna array, or an array unit within an antenna array, in which the array unit includes one or more antenna elements. For illustrative purposes, at least a portion of the AUT 202 may be implemented using the array unit 102 shown in FIG. 1. However, this is not intended to limit the scope of the present disclosure.

The antenna measurement system 200 may include, but is not limited to, a reference antenna 210, an analyzer 220, and a signal generator 232. The reference antenna 210 is arranged to receive electrical signals ES1 and ES2 to transmit an electromagnetic signal EM toward the AUT 202. The AUT 202 can generate an output signal R_{OUT} in response to the electromagnetic signal EM. In the present embodiment, the reference antenna 210 may be implemented as a dual-polarized antenna, which is capable of radiating two orthogonally polarized that are combined to produce the electromagnetic signal EM. The polarization type of the electromagnetic signal EM can be determined based on the respective amplitudes the electrical signals ES1 and ES2 and/or the phase relationship between the electrical signals ES1 and ES2. By way of example but not limitation, the reference antenna 210 may radiate horizontally and vertically polarized waves simultaneously according to the electrical signals ES1 and ES2. As another example, the reference antenna 210 may radiate right-hand and left-hand circularly polarized waves simultaneously according to the electrical signals ES1 and ES2.

The analyzer 220, coupled to the AUT 202, is configured to receive the output signal R_{OUT} from the AUT 202. The analyzer 220 is further configured to generate the input signal R_{IN}, and generate the analysis data DA according to the input signal R_{IN} and the output signal R_{OUT}. For example, the analyzer 220 may be implemented using a network analyzer or a vector network analyzer (VNA). The input signal R_{IN} may include, but is not limited to, source signal(s) generated from one or more input ports of the analyzer 220. The analyzer 220 can measure S-parameters (scattering parameters) according to the input signal R_{IN} and the output signal R_{OUT}. The measured S-parameters can serve as at least a portion of the analysis data DA.

The signal generator 232, coupled to the reference antenna 210 and the analyzer 220, is configured to process the input signal R_{IN} according to the control information CI to thereby generate the electrical signals ES1 and ES2. By way of example but not limitation, the signal generator 232 may perform amplitude scaling and/or phase shifting on the input signal R_{IN} according to the control information CI, and accordingly generate the electrical signals ES1 and ES2. As another example, the signal generator 232 may adjust the signal characteristics of the input signal R_{IN} according to the control information CI, and accordingly generate the electrical signals ES1 and ES2. In the present embodiment, the signal generator 232 can be at least a portion of an electronic device 230 that is disposed between the reference antenna 210 and the analyzer 220.

In operation, the analyzer 220 provides the input signal R_{IN} to the electronic device 230 (or the signal generator 232). The input signal R_{IN} may include one or more radio frequency (RF) signals. The electronic device 230 (or the signal generator 232) processes the input signal R_{IN} according to the control information CI, and accordingly generates the electrical signals ES1 and ES2. The amplitude and/or phase of at least one of the electrical signals ES1 and ES2 is determined according to the control information CI. The reference antenna 210 is excited by the electrical signals ES1 and ES2 to produce the electromagnetic signal EM, the polarization type and/or polarization direction of which is determined according to the control information CI. In addition, the electromagnetic signal EM may include a plurality of polarized waves emitted at different times, and the polarized waves can correspond to different polarization directions. By way of example but not limitation, the reference antenna 210 may emit linearly polarized waves corresponding to different polarization directions according to the electrical signals ES1 and ES2, and the linearly polarized waves can serve as the electromagnetic signal EM. As another example, the reference antenna 210 may emit circularly polarized waves corresponding to different polarization directions according to the electrical signals ES1 and ES2, and the circularly polarized waves can serve as the electromagnetic signal EM.

Furthermore, the antenna elements or array units of the AUT 202 are configured to couple the electromagnetic signal EM into multiple electrical signals (e.g., RF signals corresponding to the horizontal and vertical field components of the electromagnetic signal EM), which are combined within the AUT 202 to produce the output signal R_{OUT}. The output signal R_{OUT} can reflect the responses of the AUT 202 to the polarized waves corresponding to different polarization directions. Next, the analyzer 220 can analyze the input signal R_{IN} and the output signal R_{OUT} to generate the analysis data DA, which may indicate the signal transmission characteristics of the AUT 202 under a system configuration determined by the control information CI. The antenna measurement system 200 can process the analysis data DA according to a data processing operation corresponding to the control information CI, thereby determining the polarization characteristics of the AUT 202.

For example, the antenna measurement system 200 may further include, but is not limited to, a processing circuit 240 and a controller 250. The processing circuit 240, coupled to the analyzer 220, is configured to obtain a polarization characteristic of the AUT 202 by applying a predetermined data processing operation to the analysis data DA. The polarization characteristic may include, but is not limited to, an axial ratio, gain, or other features of the AUT 202. The controller 250, coupled to the processing circuit 240 and the electronic device 230 (or signal generator 232), is configured to provide the control information CI according to the predetermined data processing operation. In the present embodiment, after determining or configuring the predetermined data processing operation, the antenna measurement system 200 can generate the control information CI corresponding to the predetermined data processing operation. The control information CI can be provided for determining the polarization type and/or polarization direction of the electromagnetic signal EM. For example, the controller 250 may determine the control information CI according to the predetermined data processing operation, and provide the control information CI to the electronic device 230, which operates according to a control configuration specified by the control information CI. In some embodiments, the processing circuit 240 may generate the control information CI according to the predetermined data processing operation. In other words, the controller 250 may be optional, or embedded within the processing circuit 240.

By controlling the excitation signals of the reference antenna 210 through the electronic device 230, the antenna measurement system 200 can drive the reference antenna 210 to emit a predetermined electromagnetic signal to the AUT 202, and measure a polarization characteristic of the AUT 202 according to a data processing operation corresponding to the predetermined electromagnetic signal. With the use of the electronic device 230, the antenna measurement system 200 can effectively identify the polarization characteristic of the AUT 202.

To facilitate understanding of the present disclosure, some embodiments are provided below to further describe the proposed antenna measurement scheme. However, this is not intended to limit the scope of the present disclosure. Those skilled in the art will recognize that other implementations employing the architecture shown in FIG. 2 also fall within the scope of the present disclosure. Additionally, in some embodiments, the proposed antenna measurement scheme may be applied to far-field antenna measurement systems and compact antenna test ranges (CATRs) without departing from the scope of the present disclosure.

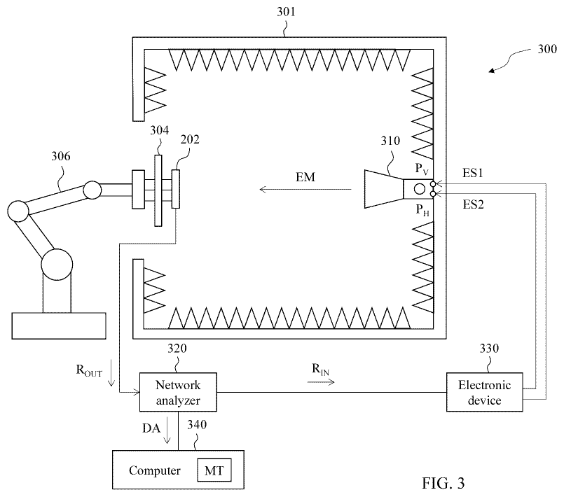

FIG. 3 illustrates an implementation of the antenna measurement system 200 shown in FIG. 2 in accordance with some embodiments of the present disclosure. In the present embodiment, the antenna measurement system 300 may be used to measure the circular, elliptical or linear polarization characteristics of the AUT 202 shown in FIG. 2. The antenna measurement system 300 may include, but is not limited to, an anechoic chamber 301, a mechanical component 304, a position controller 306, a dual-polarized antenna 310, a network analyzer 320, and an electronic device 330. The anechoic chamber 301 is arranged to provide a shielded environment free of electromagnetic wave reflections and interference, enhancing measurement and testing accuracy. The mechanical component 304 is arranged to secure the AUT 202, thereby facilitating the connection between the AUT 202 and the position controller 306.

The position controller 306 is configured to adjust the position of the mechanical component 304 to thereby control the orientation of the AUT 202. By way of example but not limitation, the position controller 306 may move the AUT 202 to alter the azimuth angle of the dual-polarized antenna 310 relative to the AUT 202. In the embodiment shown in FIG. 3, the position controller 306 may be implemented using, but not limited to, a robotic arm. Note that the mechanical component 304 may be optional or designed within the AUT 202 as long as the orientation of the AUT 202 can be controlled by the position controller 306. For example, the AUT 202 may include a structural component that allows the AUT 202 to be fixed to the position controller 306, enabling the position controller 306 to control the orientation of the AUT 202. The mechanical component 304 may be a part of or designed within the AUT 202.

In addition, the dual-polarized antenna 310, the network analyzer 320 and the electronic device 330 can serve as implementations of the reference antenna 210, the analyzer 220 and the electronic device 230 shown in FIG. 2 respectively. In the present embodiment, the dual-polarized antenna 310 may include the input ports P_{V} and P_{H}, and may be implemented as a dual-polarized horn antenna. The input ports P_{V} and P_{H} can be arranged to receive the electrical signals ES1 and ES2 respectively, which correspond to the vertical and horizontal polarization components of the electromagnetic signal EM respectively. The input signal R_{IN} generated by the network analyzer 320 may include one or more source signals transmitted from one or more ports. The electronic device 330 can perform amplitude scaling and/or phase shifting on the one or more source signals included in the input signal R_{IN}, and accordingly generate the electrical signals ES1 and ES2.

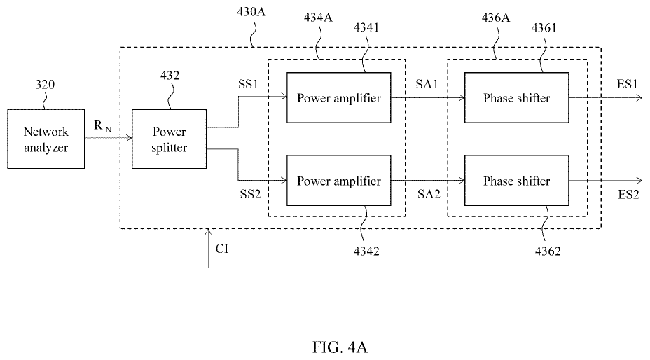

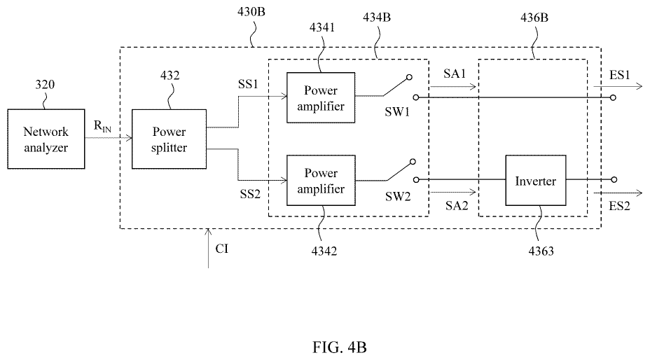

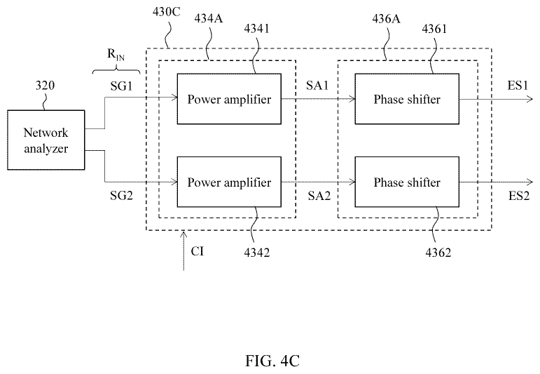

For example, referring to FIG. 4A, an implementation of the electronic device 330 shown in FIG. 3 is illustrated in accordance with some embodiments of the present disclosure. In the embodiment shown in FIG. 4A, the input signal R_{IN} may be a source signal (e.g., an RF signal) outputted from a port of the network analyzer 320. The electronic device 430A includes, but is not limited to, a power splitter 432, an amplitude scaling stage 434A and a phase shifting stage 436A. The power splitter 432, the amplitude scaling stage 434A and the phase shifting stage 436A can serve as an embodiment of the signal generator 232 shown in FIG. 2.

The power splitter 432 is configured to divide the input signal R_{IN} into electrical signals SS1 and SS2. The amplitude scaling stage 434A is configured to process the input signal R_{IN} to generate amplified signals SA1 and SA2 according to the control information CI. For example, the amplitude scaling stage 434A may include power amplifiers 4341 and 4342, which can be configured to adjust the amplitude of the electrical signals SS1 and SS2, respectively. In addition, the phase shifting stage 436A is configured to processes the amplified signals SA1 and SA2 according to the control information CI, and accordingly generate the electrical signals ES1 and ES2. For example, the phase shifting stage 436A may include phase shifters 4361 and 4362, which can be configured to perform phase shifting operations on the amplified signals SA1 and SA2, respectively. Thus, the respective amplitudes/phases of the electrical signals ES1 and ES2 can be independently controlled.

In some embodiments, the phase shifter 4361 or the phase shifter 4362 may be optional. By way of example but not limitation, the electromagnetic signal EM shown in FIG. 3 may be determined according to a phase difference between the electrical signals ES1 and ES2. One of the phase shifters 4361 and 4362 can be a phase shifter capable of providing a phase shift from 0° to 360°, while the other of the phase shifters 4361 and 4362 can be optional.

FIG. 4B illustrates another implementation of the electronic device 330 shown in FIG. 3 is illustrated in accordance with some embodiments of the present disclosure. In the embodiment shown in FIG. 4B, the electronic device 430C may include the power splitter 432 shown in FIG. 4A, an amplitude scaling stage 434B and a phase shifting stage 436B. The power splitter 432, the amplitude scaling stage 434B and the phase shifting stage 436B can serve as an embodiment of the signal generator 232 shown in FIG. 2.

The amplitude scaling stage 434B can be configured to selectively output the amplified signal SA1/SA2 to the phase shifting stage 436B. By way of example but not limitation, the structure of the amplitude scaling stage 434B is identical/similar to that of the amplitude scaling stage 434A shown in FIG. 4A except for the switches SW1 and SW2. The switch SW1/SW2 can be selectively switched on according to the control information CI. Note that the switch SW1/SW2 may be optional. For example, the equivalent function may be achieved by selectively enabling the power amplifier 4341/4342 according to control information CI.

The phase shifting stage 436B can be configured to provide a phase shift of 0° or 180° for the amplified signal SA1/SA2. In the example of FIG. 4B, the phase shifting stage 436B may include an inverter 4363, which is configured to selectively apply a phase shift of 0° or 180° to the amplified signal SA2. Alternatively, a bypass path (not shown) may be connected in parallel with the inverter 4363 which can be configured to apply a phase shift of 180° to the amplified signal SA2. The phase shifting stage 436B can apply a phase shift of 0° to the amplified signal SA2 when the bypass path is enabled, and apply a phase shift of 180° to the amplified signal SA2 when the bypass path is disabled.

In operation, the electronic device 430B can drive the dual-polarized antenna 310 shown in FIG. 3 to emit two pairs of orthogonally linearly polarized waves through the switching of the switches SW1 and SW2 and the phase shift provided by the phase shifting stage 436B. For example, when the switch SW1 is switched on and the switch SW2 is switched off, the electronic device 430B can generate the electrical signals ES1 and ES2 having normalized amplitudes of 1 and 0, thereby driving the dual-polarized antenna 310 shown in FIG. 3 to emit a first linearly polarized wave (e.g. a linearly polarized wave with a 0° polarization direction). When the switch SW1 is switched off and the switch SW2 is switched on, the phase shifting stage 436B can be configured to apply a phase shift of 0° to the amplified signal SA2. The electronic device 430B can generate the electrical signals ES1 and ES2 having normalized amplitudes of 0 and 1, thereby driving the dual-polarized antenna 310 shown in FIG. 3 to emit a second linearly polarized wave (e.g. a linearly polarized wave with a 900 polarization direction). The first and second linearly polarized waves can serve as a pair of orthogonally linearly polarized waves.

In addition, when the switches SW1 and SW2 are switched on, and the phase shifting stage 436B is configured to apply a phase shift of 0° to the amplified signal SA2, the electronic device 430B may generate the electrical signals ES1 and ES2 of equal amplitude, thereby driving the dual-polarized antenna 310 shown in FIG. 3 to emit a third linearly polarized wave (e.g. a linearly polarized wave with a 450 polarization direction). When the switches SW1 and SW2 are switched on, and the phase shifting stage 436B is configured to apply a phase shift of 180° to the amplified signal SA2, the electronic device 430B may generate the electrical signals ES1 and ES2 of equal amplitude but opposite polarity, thereby driving the dual-polarized antenna 310 shown in FIG. 3 to emit a fourth linearly polarized wave (e.g. a linearly polarized wave with a −45° or 135° polarization direction). The third and fourth linearly polarized waves can serve as a pair of orthogonally linearly polarized waves.

FIG. 4C illustrates another implementation of the electronic device 330 shown in FIG. 3 in accordance with some embodiments of the present disclosure. In the embodiment shown in FIG. 4C, the input signal R_{IN} may include source signals SG1 and SG2 outputted from two ports of the network analyzer 320. The electronic device 430C can independently control the respective amplitudes/phases of the electrical signals ES1 and ES2 according to the control information CI. In addition, the amplitude scaling stage 434A and the phase shifting stage 436A shown in FIG. 4C can serve as an implementation of the signal generator 232 shown in FIG. 2. In some examples, the phase shifter 4361 or the phase shifter 4362 may be optional; in some examples, one of the phase shifters 4361 and 4362 can be a phase shifter capable of providing a phase shift from 0° to 360°, while the other of the phase shifters 4361 and 4362 can be optional. As the structure of the electronic device 430C is substantially identical/similar to that of the electronic device 430A shown in FIG. 4A except that the amplitude scaling stage 434A shown in FIG. 4C can receive the input signal R_{IN} without through a power splitter, repeated description is omitted here for brevity.

Note that the circuit structures shown in FIG. 4A, FIG. 4B and FIG. 4C are provided for illustrative purposes, and are not intended to limit the scope of the present disclosure. The electronic device 330 shown in FIG. 3 may be implemented using other structures capable of controlling the amplitudes and/or phases of the electrical signals ES1 and ES2 without departing from the scope of the present disclosure.

Referring again to FIG. 3, the antenna measurement system 300 may further include a computing device 340. For example, at least a portion of the computing device 340 may be implemented using the processing circuit 240 shown in FIG. 2; as another example, at least a portion of the computing device 340 may be implemented using the processing circuit 240 and the controller 250 shown in FIG. 2. In the embodiment shown in FIG. 3, the computing device 340 may be implemented as a personal computer, and may generate the control information CI according to the predetermined data processing operation MT. However, this is not intended to limit the scope of the present disclosure. In some embodiments, the control information CI may be provided to the electronic device 330 by a controller external to the computing device 340, such as the controller 250 shown in FIG. 2.

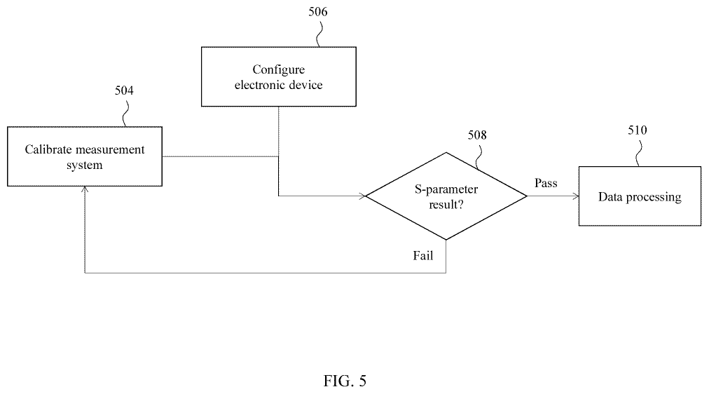

FIG. 5 is a flow chart of the measurement process in the antenna measurement system 300 shown in FIG. 3 in accordance with some embodiments of the present disclosure. Referring to FIG. 5 and also to FIG. 3, in step 504, the antenna measurement system 300 is calibrated. The network analyzer 320, the electronic device 330 and the computing device 340 can be powered on to begin operation. For example, frequency response calibration may be performed on the antenna measurement system 300 to ensure that the network analyzer 320 exhibits a smooth frequency response across an operating frequency range thereof. As another example, the operating frequency and power output of the network analyzer 320 are configured. As still another example, power calibration may be performed on the antenna measurement system 300 to ensure that the input signal R_{IN} provided by the network analyzer 320 have accurate and stable power levels. As still another example, the measurement configuration for determining a polarization characteristic (e.g., an axial ratio) of the AUT 202 is established. As still another example, standard antennas with known polarization characteristics can be used for performing system phase calibration on the antenna measurement system 300.

In step 506, the electronic device 330 is configured. For example, in a case where the antenna measurement system 300 is set to a first measurement configuration for determining a polarization characteristic (e.g., an axial ratio) of the AUT 202, the computing device 340 (or a controller external to the computing device 340) can set the predetermined data processing operation MT to a first data processing operation, and provide the control information CI specifying a first control configuration. In other words, the first data processing operation corresponds to, or is related to, the control information CI specifying the first control configuration. The electronic device 330 can process the input signal R_{IN} according to the first control configuration specified by the control information CI.

Additionally, in a case where the antenna measurement system 300 is set to a second measurement configuration (different from the first measurement configuration) for determining a polarization characteristic (e.g., an axial ratio) of the AUT 202, the computing device 340 (or a controller external to the computing device 340) can set the predetermined data processing operation MT to a second data processing operation (different from the first data processing operation), and provide the control information CI specifying a second control configuration (different from the first control configuration). In other words, the second data processing operation corresponds to, or is related to, the control information CI specifying the second control configuration. The electronic device 330 can process the input signal R_{IN} according to the second control configuration specified by the control information CI.

In step 508, measurement results of S-parameters are evaluated to determine whether they meet design specifications or predefined conditions. If yes, proceed to step 510; otherwise, return to step 504. For example, the network analyzer 320 can generate the analysis data DA (including the measurement results of S-parameters) according to the input signal R_{IN} and the output signal R_{OUT}. The computing device 340 can collect the analysis data DA and determine whether the measurement results meet the design specifications.

By way of example but not limitation, when the analysis data DA indicates that the transmission coefficient S21 is greater than or equal to a predetermined value, the computing device 340 may determine that the measurement results meet the design specifications or pass the evaluation, and then execute step 510. In some examples, if the analysis data DA indicates that the transmission coefficient S21 is less than the predetermined value, the computing device 340 may determine that the measurement results do not meet the design specifications or fail the evaluation. The antenna measurement system 300 may repeat the measurement process starting from step 504 to reconfigure the operating frequency and/or power output of the network analyzer 320. Alternatively, when the computing device 340 determines that the measurement results do not meet the design specifications, the current AUT may be marked for repair, and the antenna measurement system may proceed to measure the next AUT.

In step 510, a data processing operation related to the control information CI is applied to the analysis data DA to obtain or determine the circular or elliptical polarization characteristics of the AUT 202. For example, the computing device 340 may calculate the axial ratio of the AUT 202 by applying the predetermined data processing operation MT to the analysis data DA, thereby evaluating the circular polarization performance of the A U T 202.

For illustrative purposes, some polarization diagrams of the electromagnetic signal EM formed by the electronic device 330 under different control configurations are provided below to further describe data processing operations utilized by the antenna measurement system 300. However, this is not intended to limit the scope of the present disclosure. Those skilled in the art will understand that the antenna measurement system 300 shown in FIG. 3 may employ other data processing operations to determine the polarization characteristics of the AUT 202 without departing from the scope of the present disclosure.

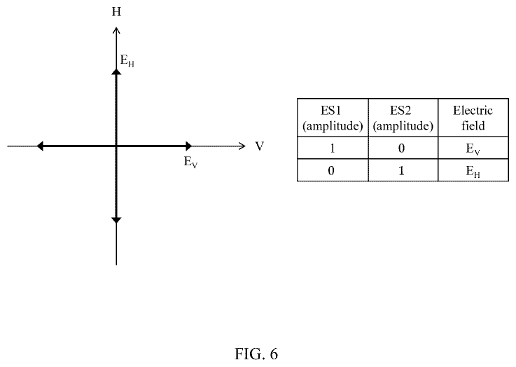

FIG. 6 is a diagram illustrating the locus of the tip of the electric field vector associated with the electromagnetic signal EM shown in FIG. 3, emitted by the dual-polarized antenna 310 when the antenna measurement system 300 operates in a dual-linear polarization measurement configuration to determine the polarization characteristic of the AUT 202, in accordance with some embodiments of the present disclosure. Referring to FIG. 6 and also to FIG. 3, the predetermined data processing operation MT utilized by the computing device 340 can be a dual-linear polarization data processing operation that is determined according to the dual-linear polarization measurement configuration. The electronic device 330 generates the electrical signals ES1 and ES2 according to the control information CI (which corresponds to the dual-linear polarization data processing operation or the dual-linear polarization measurement configuration), and accordingly drives the dual-polarized antenna 310 to emit orthogonally linearly polarized waves as the electromagnetic signal EM.

For example, the electrical signals ES1 and ES2 correspond to the vertical and horizontal polarization components of the electromagnetic signal EM, respectively. The electronic device 330 can generate the electrical signals ES1 and ES2 having normalized amplitudes of 1 and 0 according to the control information CI, and accordingly drive the dual-polarized antenna 310 to emit a vertically polarized wave included in the electromagnetic signal EM. The electric field of the vertically polarized wave is represented by Ev. In addition, the electronic device 330 can generate the electrical signals ES1 and ES2 having normalized amplitudes of 0 and 1 according to the control information CI, and accordingly drive the dual-polarized antenna 310 to emit a horizontally polarized wave included in the electromagnetic signal EM. The electric field of the horizontally polarized wave is represented by E_{H}.

In addition, the output signal R_{OUT}, generated from the AUT 202 in response to the electromagnetic signal EM, may include a first component E_{RV} and a second component E_{RH}. The first component E_{RV} is generated in response to the vertically polarized wave, and the second component E_{RH} is generated in response to the horizontally polarized wave. The first component E_{RV} and the second component E_{RH} of the output signal R_{OUT} can be expressed as follows:

$${E}_{RV} = {V}_{A} ( cos {V}_{P} + j sin {V}_{P} ) \qquad ( 1 )$$

$${E}_{RH} = {H}_{A} ( cos {H}_{P} + j sin {H}_{P} ) \qquad ( 2 )$$

where V_{A} and V_{P} represent the amplitude and phase of the first component E_{RV} respectively, and H_{A} and H_{P} represent the amplitude and phase of the second component E_{RH} respectively. The network analyzer 320 can prodive the analysis data DA to the computing device 340 according to the output signal R_{OUT} and the input signal R_{IN}.

Using the predetermined data processing operation MT, the computing device 340 can process the analysis data DA to obtain the respective amplitudes and phases of the first component E_{RV} and the second component E_{RH}, and accordingly determine the polarization characteristic of the AUT 202. For example, the computing device 340 may utilize data collected by the network analyzer 320 (e.g., transmission coefficients included in the analysis data DA) and the control configuration specified by the control information CI to determine the amplitude V_{A}, the phase V_{P}, the amplitude H_{A} and the phase H_{P}. The computing device 340 can derive the left-hand circularly polarized electric field E_{LHCP} and the right-hand circularly polarized electric field E_{RHCP} according to the amplitude V_{A}, the phase V_{P}, the amplitude H_{A} and the phase H_{P}:

$${E}_{LHCP} = \frac{1}{\sqrt{2}} [ {H}_{A} cos {H}_{P} + {V}_{A} sin {V}_{P} + j ( {H}_{A} sin {H}_{P} - {V}_{A} cos {V}_{P} ) ] \qquad ( 3 )$$

$${E}_{RHCP} = \frac{1}{\sqrt{2}} [ {H}_{A} cos {H}_{P} - {V}_{A} sin {V}_{P} + j ( {H}_{A} sin {H}_{P} + {V}_{A} cos {V}_{P} ) ] \qquad ( 4 )$$

Next, the computing device 340 can calculate the power P_{LHCP} of the left-hand circularly polarized electric field E_{LHCP} and the power P_{RHCP} the right-hand circularly polarized electric field E_{RHCP}, thereby obtaining the cross-polarization discrimination (XPD) P_{dB} and the axial ratio AR:

$${P}_{LHCP} ( dB ) = 10 {log}_{10} ( \frac{{E}_{LHCP}^{2}}{377} ) \qquad ( 5 )$$

$${P}_{RHCP} ( dB ) = 10 {log}_{10} ( \frac{{E}_{RHCP}^{2}}{377} ) \qquad ( 6 )$$

$${P}_{dB} = \vert {P}_{RHCP} - {P}_{LHCP} \vert = \vert 20 {log}_{10} ( \frac{{E}_{RHCP}}{{E}_{LHCP}} ) \vert \qquad ( 7 )$$

$$AR = 20 {log}_{10} ( \frac{1 + e}{1 - e} ) \qquad ( 8 )$$

where 377 ohm represents the wave impedance in free space, E_{LHCP}² represents the squared amplitude of the left-hand circularly polarized electric field E_{LHCP}, E_{RHCP}² represents the squared amplitude of the right-hand circularly polarized electric field E_{RHCP}, and

$$e = 10 \frac{- {P}_{dB}}{20} .$$

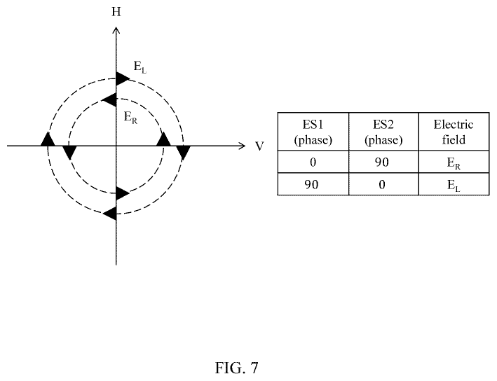

FIG. 7 is a diagram illustrating the locus of the tip of the electric field vector associated with the electromagnetic signal EM shown in FIG. 3, emitted by the dual-polarized antenna 310 when the antenna measurement system 300 operates in a circular polarization measurement configuration to determine the polarization characteristic of the AUT 202, in accordance with some embodiments of the present disclosure. Referring to FIG. 7 and also to FIG. 3, the predetermined data processing operation MT utilized by the computing device 340 can be a circular polarization data processing operation that is determined according to the circular polarization measurement configuration. The electronic device 330 generates the electrical signals ES1 and ES2 according to the control information CI (which corresponds to the circular polarization data processing operation or the circular polarization measurement configuration), and accordingly drives the dual-polarized antenna 310 to emit right-hand circularly polarized waves and left-hand circularly polarized waves as the electromagnetic signal EM.

For example, the electrical signals ES1 and ES2 correspond to the vertical and horizontal polarization components of the electromagnetic signal EM, respectively. The electronic device 330 can generate the electrical signals ES1 and ES2 having equal amplitudes but a phase difference of +90° or −90° according to the control information CI, and accordingly drive the dual-polarized antenna 310 to emit a right-hand circularly polarized wave and a left-hand circularly polarized wave included in the electromagnetic signal EM. The electric field of the right-hand circularly polarized wave is represented by E_{R}, and the electric field of the left-hand circularly polarized wave is represented by E_{L}.

The output signal R_{OUT}, generated by the AUT 202 in response to the electromagnetic signal EM, may include a first component E_{RR} and a second component E_{RL}. The first component E_{RR} is generated in response to a right-hand circularly polarized wave, and the second component E_{RL} is generated in response to a left-hand circularly polarized wave. Using the predetermined data processing operation MT, the computing device 340 can process the analysis data DA to obtain the respective powers of the first component E_{RR} and the second component E_{RL}, and accordingly determine the polarization characteristic of the AUT 202. For example, the computing device 340 may utilize data collected by the network analyzer 320 (e.g., transmission coefficients included in the analysis data DA) and the control configuration specified by the control information CI to determine the respective powers P_{RHCP} and P_{LHCP} of the first component E_{RR} and the second component E_{RL}:

$${P}_{RHCP} ( dB ) = 10 {log}_{10} ( \frac{{E}_{RR}^{2}}{377} ) \qquad ( 9 )$$

$${P}_{LHCP} ( dB ) = 10 {log}_{10} ( \frac{{E}_{RL}^{2}}{377} ) \qquad ( 10 )$$

where 377 ohm represents the wave impedance in free space, E_{RR}² represents the squared amplitude of the first component E_{RR}, and

$${E}_{RL}^{2}$$

represents the squared amplitude of the second component E_{RL}. Next, the computing device 340 can calculates the cross-polarization discrimination P_{dB} and the axial ratio AR according to the above expressions (7) and (8). As those skilled in the art can understand the details of obtaining the axial ratio of the AUT 202 using the circular polarization measurement configuration after reading the above paragraphs directed to FIG. 1 to FIG. 6, further description is omitted here for brevity.

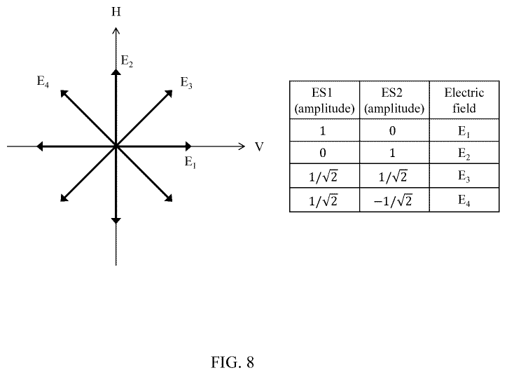

FIG. 8 is a diagram illustrating the locus of the tip of the electric field vector associated with the electromagnetic signal EM shown in FIG. 3, emitted by the dual-polarized antenna 310 when the antenna measurement system 300 operates in a dual-orthogonal polarization measurement configuration to determine the polarization characteristic of the AUT 202, in accordance with some embodiments of the present disclosure. Referring to FIG. 8 and also to FIG. 3, the predetermined data processing operation MT utilized by the computing device 340 can be a dual-orthogonal polarization data processing operation that is determined according to the dual-orthogonal polarization measurement configuration. The electronic device 330 generates the electrical signals ES1 and ES2 according to the control information CI (which corresponds to the dual-orthogonal polarization data processing operation or the dual-orthogonal polarization measurement configuration), and accordingly drives the dual-polarized antenna 310 to emit two pairs of orthogonally linearly polarized waves as the electromagnetic signal EM.

For example, the electrical signals ES1 and ES2 correspond to the vertical and horizontal polarization components of the electromagnetic signal EM, respectively. The electronic device 330 can generate the electrical signals ES1 and ES2 having normalized amplitudes of 1 and 0 according to the control information CI, and accordingly drive the dual-polarized antenna 310 to emit a first linearly polarized wave included in the electromagnetic signal EM (or referred to as a linearly polarized wave with a 0° polarization direction). The electric field of the first linearly polarized wave is represented by E₁. Then, the AUT 202 generates a first component E_{R1} of the output signal R_{OUT} in response to the first linearly polarized wave with the electric field E₁. The electronic device 330 can further generate the electrical signals ES1 and ES2 having normalized amplitudes of 0 and 1 according to the control information CI, and accordingly drive the dual-polarized antenna 310 to emit a second linearly polarized wave included in the electromagnetic signal EM (or referred to as a linearly polarized wave with a 90° polarization direction). The electric field of the second linearly polarized wave is represented by E₂. Then, the AUT 202 generates a second component E_{R2} of the output signal R_{OUT} in response to the second linearly polarized wave with the electric field E₂.

In addition, the electronic device 330 can generate the electrical signals ES1 and ES2 having normalized amplitudes of

$$\frac{1}{\sqrt{2}} and \frac{1}{\sqrt{2}}$$

according to the control information CI, and accordingly drive the dual-polarized antenna 310 to emit a third linearly polarized wave included in the electromagnetic signal EM (or referred to as a linearly polarized wave with a 45° polarization direction). The electric field of the third linearly polarized wave is represented by E₃. Then, the AUT 202 generates a third component E_{R3} of the output signal R_{OUT} in response to the third linearly polarized wave with the electric field E₃. Similarly, the electronic device 330 can further generate the electrical signals ES1 and ES2 having normalized amplitudes of

$$\frac{1}{\sqrt{2}} and - \frac{1}{\sqrt{2}}$$

according to the control information CI, and accordingly drive the dual-polarized antenna 310 to emit a fourth linearly polarized wave included in the electromagnetic signal EM (or referred to as a linearly polarized wave with a 135° polarization direction). The electric field of the fourth linearly polarized wave is represented by E₄. Then, the AUT 202 generates a fourth component E_{R4} of the output signal R_{OUT} in response to the fourth linearly polarized wave with the electric field E₄.

Next, the network analyzer 320 can prodive the analysis data DA to the computing device 340 according to the output signal R_{OUT} and the input signal R_{IN}. Using the predetermined data processing operation MT, the computing device 340 can process the analysis data DA to obtain the respective amplitudes of the first component E_{R1}, the second component E_{R2}, the third component E_{R3} and the fourth component E_{R4}, and accordingly determine the polarization characteristic of the AUT 202. For example, the computing device 340 may utilize data collected by the network analyzer 320 (e.g., transmission coefficients included in the analysis data DA) and the control configuration specified by the control information CI to determine the respective amplitudes of the first component E_{R1}, the second component E_{R2}, the third component E_{R3} and the fourth component E_{R4}, thereby calculating the inclination T of the polarization ellipse relative to the vertical/horizontal axis:

$$τ = \frac{1}{2} {tan}^{- 1} \frac{{E}_{R 3}^{2} - {E}_{R 4}^{2}}{{E}_{R 1}^{2} - {E}_{R 2}^{2}} \qquad ( 11 )$$

where

$${E}_{R 1}^{2}$$

represents the squared amplitude of the first component E_{R1},

$${E}_{R 2}^{2}$$

represents the squared amplitude of the second component E_{R2},

$${E}_{R 3}^{2}$$

represents the squared amplitude of the third component E_{R3}, and

$${E}_{R 4}^{2}$$

represents the squared amplitude of the fourth component E_{R4}. Next, the computing device 340 can calculates the axial ratio AR of the AUT 202:

$$AR = \sqrt{\frac{{E}_{R 1}^{2} {cos}^{2} τ + \frac{1}{2} ( {E}_{R 3}^{2} - {E}_{R 4}^{2} ) sin 2 τ + {E}_{R 2}^{2} {sin}^{2} τ}{{E}_{R 1}^{2} {sin}^{2} τ - \frac{1}{2} ( {E}_{R 3}^{2} - {E}_{R 4}^{2} ) sin 2 τ + {E}_{R 2}^{2} {cos}^{2} τ}} \qquad ( 12 )$$

In some embodiments, the antenna measurement system 300 may utilize different pairs of orthogonally linearly polarized waves for antenna measurement without departing from the scope of the present disclosure. For example, in addition to the pair of orthogonally linearly polarized waves with 0° and 90° polarization directions, the electronic device 330 may drive the dual-polarized antenna 310 to emit a pair of orthogonally linearly polarized waves with 60° and 150° polarization directions according to the control information CI. The antenna measurement system 300 can utilize these pairs of orthogonally linearly polarized waves to perform the antenna measurement.

As those skilled in the art can understand the details of obtaining the axial ratio of the AUT 202 using the dual-orthogonal polarization measurement configuration after reading the above paragraphs directed to FIG. 1 to FIG. 7, further description is omitted here for brevity.

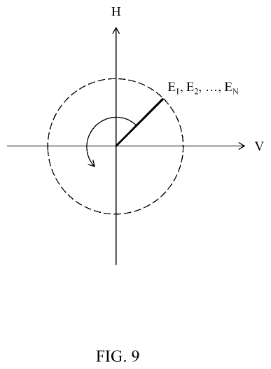

FIG. 9 is a diagram illustrating the locus of the tip of the electric field vector associated with the electromagnetic signal EM shown in FIG. 3, emitted by the dual-polarized antenna 310 when the antenna measurement system 300 operates in a rotating linear polarization measurement configuration to determine the polarization characteristic of the AUT 202, in accordance with some embodiments of the present disclosure. Referring to FIG. 9 and also to FIG. 3, the predetermined data processing operation MT utilized by the computing device 340 can be a rotating linear polarization data processing operation that is determined according to the rotating linear polarization measurement configuration. The electronic device 330 generates the electrical signals ES1 and ES2 according to the control information CI (which corresponds to the rotating linear polarization data processing operation or the rotating linear polarization measurement configuration), and accordingly drives the dual-polarized antenna 310 to emit a plurality of linearly polarized waves with time-varying polarization directions as the electromagnetic signal EM.

For example, the electrical signals ES1 and ES2 correspond to the vertical and horizontal polarization components of the electromagnetic signal EM, respectively. The electronic device 330 can generate the electrical signals ES1 and ES2 having different amplitude combinations, and accordingly drive the dual-polarized antenna 310 to emit corresponding linearly polarized waves with different polarization directions. In other words, the electromagnetic signal EM may include a plurality of linearly polarized waves with varying polarization directions. The respective electric fields of the linearly polarized wave are represented by E₁ to E_{N}. In the present embodiment, the polarization direction of the electromagnetic signal EM may rotate incrementally over time by 180° to facilitate axial ratio measurement.

The AUT 202 can generate a component Eⱼ of the output signal R_{OUT} in response to a linearly polarized wave with the electric field E_{Rj}, where j=1, 2, . . . N. In other words, the output signal R_{OUT}, generated from the AUT 202 in response to multiple linearly polarized waves of the electromagnetic signal EM, includes multiple components E_{R1} to E_{RN}. Next, the network analyzer 340 can prodive the analysis data DA to the computing device 340 according to the output signal R_{OUT} and the input signal R_{IN}. Using the predetermined data processing operation MT, the computing device 340 can process the analysis data DA to obtain the respective amplitudes of the components E_{R1} to E_{RN}, and accordingly determine the polarization characteristic of the AUT 202. For example, the computing device 340 may utilize data collected by the network analyzer 320 (e.g., transmission coefficients included in the analysis data DA) and the control configuration specified by the control information CI to determine the respective amplitudes of the components E_{R1} to E_{RN}, thereby calculating the axial ratio of the AUT 202.

Note that the antenna measurement system 300 can change the linear polarization direction of the electromagnetic signal EM by adjusting the excitation signals (i.e., the electrical signals ES1 and ES2) applied to the dual-polarized antenna 310. This approach eliminates the need for mechanical rotation of the dual-polarized antenna 310, enabling rapid and precise determination of the polarization characteristics of the AUT 202.

As those skilled in the art can understand the details of obtaining the axial ratio of the AUT 202 using the rotating linear polarization measurement configuration after reading the above paragraphs directed to FIG. 1 to FIG. 8, further description is omitted here for brevity.

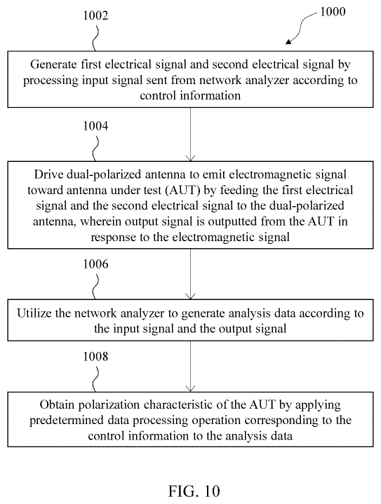

FIG. 10 is a flow chart of an exemplary antenna measurement method in accordance with some embodiments of the present disclosure. For illustrative purposes, the antenna measurement method 1000 is described below with reference to the antenna measurement system 300 shown in FIG. 3. Those skilled in the art can understand that the antenna measurement method 1000 can be applied to the antenna measurement system 200 shown in FIG. 2 without departing from the scope of the present disclosure. In some embodiments, other operations can be performed in the antenna measurement method 1000. In some embodiments, operations of the antenna measurement method 1000 may vary.

In step 1002, a first electrical signal and a second electrical signal are generated by processing an input signal sent from a network analyzer according to control information. For example, the electronic device 330 can process the input signal R_{IN} according to the control information CI, and accordingly generate the electrical signals ES1 and ES2. In some embodiments, the amplitude and the phase of at least one of the electrical signals ES1 and ES2 can be determined according to the control information CI.

In step 1004, a dual-polarized antenna driven to emit an electromagnetic signal toward an AUT by feeding the first electrical signal and the second electrical signal to the dual-polarized antenna. An output signal is outputted from the AUT in response to the electromagnetic signal. For example, the electronic device 330 can feed the electrical signals ES1 and ES2 into the input ports P_{V} and P_{H} of the dual-polarized antenna 310, thereby driving the dual-polarized antenna 310 to emit the electromagnetic signal EM toward the AUT 202. The AUT 202 generates the output signal R_{OUT} in response to the electromagnetic signal EM.

In step 1006, the network analyzer is utilized to generate analysis data according to the input signal and the output signal. For example, the network analyzer 320 can generate the analysis data DA according to the input signal R_{IN} and the output signal R_{OUT}. In some embodiments, the output signal R_{OUT} may be indicative of a combination of two electrical signals produced by each antenna element included in the AUT 202 (e.g., a combination of the electrical signals SR_{H} and SR_{V} shown in FIG. 1), and these two electrical signals correspond to two orthogonal polarization components (e.g., vertical and horizontal polarization components) of the electromagnetic signal EM respectively. The network analyzer 320 can receive the output signal R_{OUT} from the AUT 202, and generate the analysis data DA according to a relationship between the input signal R_{IN} and the output signal R_{OUT}.

In step 1008, a polarization characteristic of the AUT is obtained by applying a predetermined data processing operation corresponding to the control information to the analysis data. For example, the computing device 340 can apply the predetermined data processing operation MT to the analysis data DA to obtain the axial ratio of the AUT 202.

In some embodiments, when the predetermined data processing operation MT utilized by the computing device 340 is a first data processing operation, the electronic device 330 can generate the electrical signals ES1 and ES2 by processing the input signal R_{IN} according to a first control configuration specified by the control information CI; when the predetermined data processing operation MT utilized by the computing device 340 is a second data processing operation different from the first data processing operation, the electronic device 330 can generate the electrical signals ES1 and ES2 by processing the input signal R_{IN} according to a second control configuration (different from the first control configuration) specified by the control information CI. In other words, the control configuration specified by the control information CI corresponds to the data processing operation or the measurement configuration employed by the antenna measurement system 300.

As those skilled in the art can understand the operation of the antenna measurement method 1000 after reading the above paragraphs directed to FIG. 1 to FIG. 9, further description is omitted here for brevity.

By adjusting the signal characteristics (e.g., amplitude and/or phase) of the excitation signals for the reference antenna, the proposed antenna measurement scheme can realize rapid synthesis or modification of the polarization characteristics of the electromagnetic signal directed toward the AUT, thereby significantly enhancing the measurement efficiency and accuracy for antenna array systems with a large number of antenna elements. Even if an output signal of the AUT is produced by combining response signals corresponding to horizontal and vertical polarization components of the electromagnetic signal, the proposed antenna measurement scheme can effectively identify the polarization characteristics of the AUT.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An antenna measurement method, comprising:
generating a first electrical signal and a second electrical signal by processing an input signal sent from an analyzer according to control information;
driving a dual-polarized antenna to emit an electromagnetic signal toward an antenna under test (AUT) by feeding the first electrical signal and the second electrical signal to the dual-polarized antenna, wherein an output signal is outputted from the AUT in response to the electromagnetic signal;
utilizing the analyzer to generate analysis data according to the input signal and the output signal; and
obtaining a polarization characteristic of the AUT by applying a predetermined data processing operation corresponding to the control information to the analysis data.

2. The antenna measurement method of claim 1, wherein an amplitude and a phase of at least one of the first electrical signal and the second electrical signal are determined according to the control information.

3. The antenna measurement method of claim 1, wherein the step of generating the first electrical signal and the second electrical signal by processing the input signal according to the control information comprises:
performing amplitude scaling and phase shifting on the input signal according to the control information, and accordingly generating the first electrical signal and the second electrical signal.

4. The antenna measurement method of claim 1, wherein the step of generating the first electrical signal and the second electrical signal by processing the input signal according to the control information comprises:
when the predetermined data processing operation is a first data processing operation, generating the first electrical signal and the second electrical signal by processing the input signal according to a first control configuration specified by the control information; and
when the predetermined data processing operation is a second data processing operation different from the first data processing operation, generating the first electrical signal and the second electrical signal by processing the input signal according to a second control configuration specified by the control information, wherein the second control configuration is different from the first control configuration.

5. The antenna measurement method of claim 1, wherein the step of utilizing the analyzer to generate the analysis data according to the input signal and the output signal comprises:
utilizing the analyzer to receive the output signal from the AUT, wherein the output signal is indicative of a combination of a third electrical signal and a fourth electrical signal produced by each antenna element included in the AUT; the third electrical signal and the fourth electrical signal correspond to two orthogonal polarization components of the electromagnetic signal respectively; and
generate the analysis data according to a relationship between the input signal and the output signal.

6. The antenna measurement method of claim 1, wherein the polarization characteristic comprises an axial ratio of the AUT.

7. The antenna measurement method of claim 1, wherein the electromagnetic signal comprises a plurality of polarized waves emitted at different times, and the polarized waves correspond to different polarization directions.

8. The antenna measurement method of claim 7, wherein the polarized waves comprise a vertically polarized wave and a horizontally polarized wave; the step of obtaining the polarization characteristic of the AUT by applying the predetermined data processing operation to the analysis data comprises:
processing the analysis data to determine a first amplitude and a first phase of the first component, and a second amplitude and a second phase of the second component; and
obtaining the polarization characteristic of the AUT according to the first amplitude, the first phase, the second amplitude and the second phase.

9. The antenna measurement method of claim 7, wherein the polarized waves comprise a right-hand circularly polarized wave and a left-hand circularly polarized wave;
the output signal comprises a first component generated in response to the right-hand circularly polarized wave, and a second component generated in response to the left-hand circularly polarized wave; the step of obtaining the polarization characteristic of the AUT by applying the predetermined data processing operation to the analysis data comprises:
processing the analysis data to determine a power of the first component and a power of the second component; and
obtaining the polarization characteristic of the AUT according to the respective powers of the first component and the second component.

10. The antenna measurement method of claim 7, wherein the polarized waves comprise a first linearly polarized wave, a second linearly polarized wave orthogonal to the first linearly polarized wave, a third linearly polarized wave, and a fourth linearly polarized wave orthogonal to the third linearly polarized wave; the output signal comprises a first component generated in response to the first linearly polarized wave, a second component generated in response to the second linearly polarized wave, a third component generated in response to the third linearly polarized wave, and a fourth component generated in response to the fourth linearly polarized wave; the step of obtaining the polarization characteristic of the AUT by applying the predetermined data processing operation to the analysis data comprises:
processing the analysis data to determine respective amplitudes of the first component, the second component, the third component and the fourth component; and
obtaining the polarization characteristic of the AUT according to the respective amplitudes of the first component, the second component, the third component and the fourth component.

11. The antenna measurement method of claim 7, wherein the polarized waves comprise a plurality of linearly polarized waves oriented in different polarization directions; the output signal comprises a plurality of components generated in response to the linearly polarized waves respectively; the step of obtaining the polarization characteristic of the AUT by applying the predetermined data processing operation to the analysis data comprises:
processing the analysis data to determine respective amplitudes of the components of the output signal; and
obtaining the polarization characteristic of the AUT according to the respective amplitudes of the components of the output signal.

12. An antenna measurement system, comprising:
a dual-polarized antenna, configured to receive a first electrical signal and a second electrical signal to emit an electromagnetic signal toward an antenna under test (AUT), wherein an output signal is generated from the AUT in response to the electromagnetic signal;
an analyzer, configured to generate an input signal, receive the output signal from the AUT, and generate analysis data according to the input signal and the output signal;
a processing circuit, coupled to the analyzer, the processing circuit being configured to obtain a polarization characteristic of the AUT by applying a predetermined data processing operation to the analysis data; and
a signal generator, coupled to the dual-polarized antenna and the analyzer, the signal generator being configured to generate the first electrical signal and the second electrical signal by processing the input signal according to control information corresponding to the predetermined data processing operation.

13. The antenna measurement system of claim 12, wherein an amplitude and a phase of at least one of the first electrical signal and the second electrical signal are determined according to the control information.

14. The antenna measurement system of claim 12, wherein the polarization characteristic comprises an axial ratio of the AUT.

15. The antenna measurement system of claim 12, wherein the signal generator is configured to perform amplitude scaling and phase shifting on the input signal according to the control information, and accordingly generate the first electrical signal and the second electrical signal.

16. The antenna measurement system of claim 12, wherein when the predetermined data processing operation is a first data processing operation, the signal generator is configured to process the input signal according to a first control configuration specified by the control information; when the predetermined data processing operation is a second data processing operation different from the first data processing operation, the signal generator is configured to process the input signal according to a second control configuration specified by the control information; the second control configuration is different from the first control configuration.

17. The antenna measurement system of claim 12, further comprising:
a controller, coupled to the processing circuit and the signal generator, the controller being configured to provide the control information to the signal generator according to the predetermined data processing operation.

18. An antenna measurement system, comprising:
a dual-polarized antenna, configured to receive a first electrical signal and a second electrical signal to emit an electromagnetic signal toward an antenna under test (AUT), wherein an output signal is generated from the AUT in response to the electromagnetic signal;
an electronic device, coupled to the dual-polarized antenna, the electronic device being configured to generate the first electrical signal and the second electrical signal by performing amplitude scaling and phase shifting on an input signal; and
a network analyzer, coupled to the AUT and the electronic device, the network analyzer being configured to generate the input signal, receive the output signal from the AUT, and generate analysis data according to the input signal and the output signal.

19. The antenna measurement system of claim 18, further comprising:
a processing circuit, coupled to the network analyzer, the processing circuit being configured to obtain an axial ratio of the AUT by applying a predetermined data processing operation to the analysis data;
wherein the electronic device is configured to perform the amplitude scaling and the phase shifting on the input signal according to control information related to the predetermined data processing operation.

20. The antenna measurement system of claim 19, further comprising:
a controller, coupled to the electronic device and the processing circuit, the controller being configured to determine the control information according to the predetermined data processing operation, and provide the control information to the electronic device.
